(19) United States
(12) Patent Application Publication
(10) Pub. No.: US 2024/0159801 A1
(43) Pub. Date: May 16, 2024

(54) SYSTEMS AND METHODS FOR ESTIMATING OUTPUT CURRENT OF A CHARGE PUMP

(71) Applicant: pSemi Corporation, San Diego, CA (US)

(72) Inventors: Antony Christopher ROUTLEDGE, Basingstoke (GB); Alok Kumar MITTAL, Reading (GB)

(73) Assignee: pSemi Corporation, San Diego, CA (US)

(21) Appl. No.: 18/510,899

(22) Filed: Nov. 16, 2023

Related U.S. Application Data
(60) Provisional application No. 63/383,921, filed on Nov. 16, 2022.

(51) Int. Cl. G01R 19/00

(52) U.S. Cl. CPC G01R 19/0046; H02M 3/07

(57) ABSTRACT

The present disclosure relates to current sensing, and more particularly, to systems and methods for estimating the output current of a charge pump. In one embodiment, a method for estimating an output current of a charge pump is disclosed. The method comprises measuring, using a first sensing circuit, an input current into a switched capacitor power conversion circuit, and calculating, using a hardware processor, an estimated output current from the switched capacitor power conversion circuit as:

I_{OUT}=(I_{IN}×N)−Offset

wherein I_{OUT} is the estimated output current, I_{IN} is the measured input current, N is a multiplication or division factor of the switched capacitor power conversion circuit, and Offset is an output current offset.

### TECHNICAL FIELD

The present disclosure relates to current sensing, and more particularly, to systems and methods for estimating the output current of a charge pump.

### BACKGROUND

Many electronic products, particularly mobile computing and/or communication products and components (e.g., notebook computers, ultra-book computers, tablet devices, LCD and LED displays), require multiple voltage levels. For example, power amplifiers for radio frequency transmitters may require relatively high voltages (e.g., 12 volts (V) or more), and logic circuitry may require a low voltage level (e.g., 1-2 V). Some other circuits may require an intermediate voltage level (e.g., 5-10 V). Various configurations of switched capacitor power conversion circuits, sometimes also known as “charge pumps,” provide voltage conversion (i.e., step up, step down, or bidirectional) between a high side voltage and a low side voltage through controlled transfers of charge between capacitors in the circuit.

### SUMMARY

Embodiments of the present disclosure may provide systems and methods for estimating the output current of a charge pump. In one embodiment, a method for estimating an output current of a charge pump is disclosed. The method comprises measuring, using a first sensing circuit, an input current into a switched capacitor power conversion circuit, and calculating, using a hardware processor, an estimated output current from the switched capacitor power conversion circuit as:

I_{OUT}=(I_{IN}×N)−Offset

wherein I_{OUT} is the estimated output current, I_{IN} is the measured input current, N is a multiplication or division factor of the switched capacitor power conversion circuit, and Offset is an output current offset.

In another embodiment, an apparatus for estimating an output current of a charge pump is disclosed. The apparatus comprises a first sensing circuit to measure an input current into a switched capacitor power conversion circuit, and a hardware processor to calculate an estimated output current from the switched capacitor power conversion circuit as:

I_{OUT}=(I_{IN}×N)−Offset

wherein I_{OUT} is the estimated output current, I_{IN} is the measured input current, N is a multiplication or division factor of the switched capacitor power conversion circuit, and Offset is an output current offset.

In another embodiment, a computer-readable medium storing processor-executable instructions for estimating an output current of a charge pump is disclosed. The processor-executable instructions comprising instructions to calculate an estimated output current from a switched capacitor power conversion circuit as:

I_{OUT}=(I_{IN}×N)−Offset

wherein I_{OUT} is the estimated output current, I_{IN} is an input current into the switched capacitor power conversion circuit that is measured using a first sensing circuit, N is a multiplication or division factor of the switched capacitor power conversion circuit, and Offset is an output current offset.

In another embodiment, a method for one-time estimation of an output current offset for a charge pump is disclosed. The method comprises measuring, using a first sensing circuit, an input current into a switched capacitor power conversion circuit, and measuring, using a second sensing circuit, an output current from the switched capacitor power conversion circuit. The method continues by calculating, using a hardware processor, a first output current offset for the switched capacitor power conversion circuit using the equation:

I_{OUT}=(I_{IN}×N)−Offset

wherein I_{OUT} is the measured output current, I_{IN} is the measured input current, N is a multiplication or division factor of the switched capacitor power conversion circuit, and Offset is the first output current offset.

It is to be understood that the foregoing general description and the following detailed description are exemplary and explanatory only, and are not restrictive of the invention, as claimed.

### BRIEF DESCRIPTION OF THE DRAWINGS AND APPENDIX

FIG. 1 illustrates an example switched capacitor power conversion circuit.

FIG. 2 illustrates an example current sensing circuit for measuring an input current of a switched capacitor power conversion circuit.

FIG. 3 is a block diagram showing example components of a switched capacitor power conversion integrated circuit.

FIG. 4 illustrates example graphs developed using a one-time evaluation of a switched capacitor power conversion circuit, plotting output current offset as a function of input current into a switched capacitor power conversion integrated circuit.

FIG. 5 is an example graph plotting mean values of output current offset as a function of the input voltage into a switched capacitor power conversion integrated circuit.

### DETAILED DESCRIPTION

The following disclosure provides many different exemplary embodiments, or examples, for implementing different features of the provided subject matter. Specific simplified examples of components and arrangements are described below to explain the present disclosure. These are, of course, merely examples and are not intended to be limiting. In addition, the present disclosure may repeat reference numerals and/or letters in the various examples. This repetition is for the purpose of simplicity and clarity and does not in itself dictate a relationship between the various embodiments and/or configurations discussed.

Many electronic products, particularly mobile computing and/or communication products and components (e.g., notebook computers, ultra-book computers, tablet devices, LCD and LED displays), require multiple voltage levels. For example, power amplifiers for radio frequency transmitters may require relatively high voltages (e.g., 12 volts (V) or more), and logic circuitry may require a low voltage level (e.g., 1-2 V). Some other circuits may require an intermediate voltage level (e.g., 5-10 V). Power converters are often used to generate a lower or higher voltage from a common power source, such as a battery, to meet the power requirements of different components in electronic products.

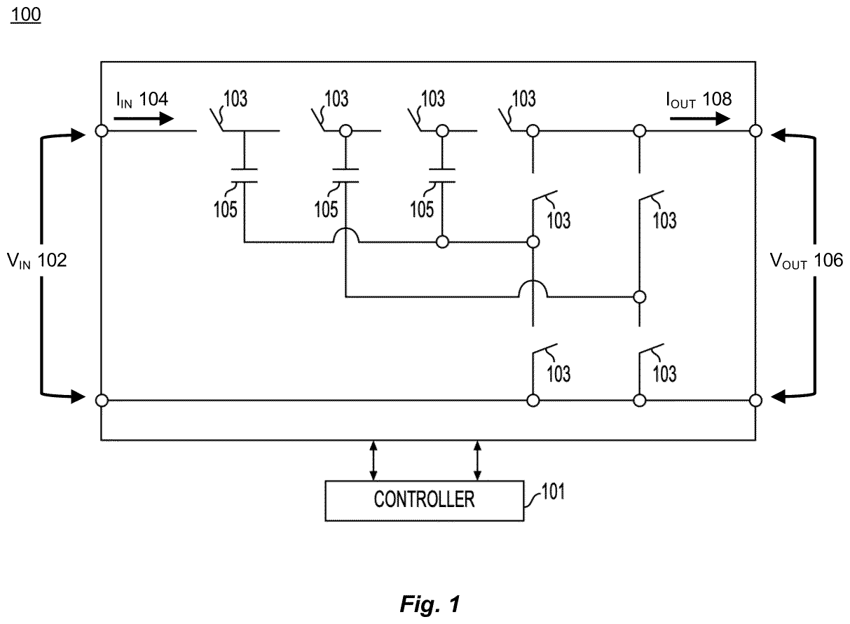

Various configurations of switched capacitor power conversion circuits (see, for example, FIG. 1, circuit 100) provide voltage conversion (i.e., step up, step down, or bidirectional) between a high side voltage (e.g., input voltage V_{IN} 102) and a low side voltage (e.g., output voltage V_{OUT} 106) through controlled transfers of charge between capacitors (e.g., 105) in the circuit. Charge pumps step up or step down an input voltage by storing a fraction of the input voltage across each capacitor (e.g., 105). Switches (e.g., 103) on both terminals of each capacitor are typically used to perform the charge transfer and configure the charge pump to provide a desired voltage conversion ratio. Control of the charge transfer between the capacitors generally makes use of circuit elements that act as “switches,” for example, diodes or FET transistors.

Electronic products may include controllers (e.g., a microcontroller) that require monitoring of various parameters of the switched capacitor power conversion circuits. Monitoring may be required, for example, for controlling or regulating the operation of the switched capacitor power conversion circuits, detecting faults in operation of the switched capacitor power conversion circuits, or for controlling or regulating other components of the electronic products. Monitored parameters may include, for example, input voltage, output voltage, temperature, input current, and output current. Measurement of such parameters may typically involve including a sensing circuit that may convert the measured parameter into a voltage or current that can be provided as an input into an analog-to-digital converter. The output of the analog-to-digital converter may be reported to the controller via a digital interface (e.g., a wired or wireless telemetry interface) as a measurement of the monitored parameter.

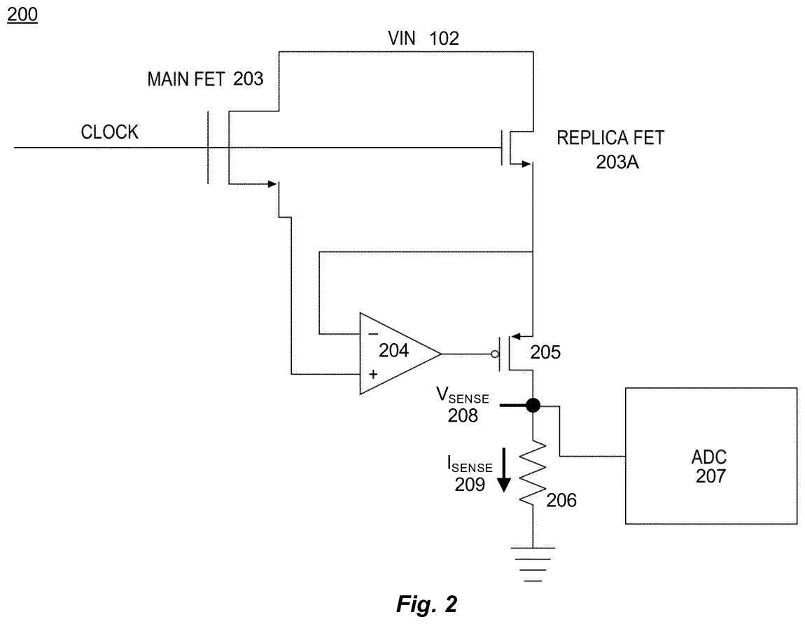

In one embodiment, measurement of an input current into a switched capacitor power conversion circuit may be performed using a sense resistor. For example, FIG. 2 depicts an example current sensing circuit 200 for measuring the input current of a switched capacitor power conversion circuit. As shown in FIG. 2, the input voltage V_{IN} 102 may be coupled to a main FET transistor 203. In this discussion, FET transistors are used as examples of semiconductor switch elements. Other types of devices (e.g., other types of transistors), and networks of multiple devices (e.g., series and/or parallel connections of transistors) can be used to form such switches. Current sensing circuit 200 may include a replica FET transistor 203A that is sized proportionately to the main FET transistor 203. For example, main FET transistor 203 may be implemented via a multiplicity of FET transistors that are similar to replica FET transistor 203A. As another example, main FET transistor 203 may be implemented via a multiplicity of smaller FET transistors, and replica FET transistor 203A may also be implemented via one or more of the smaller FET transistors. It is to be understood that use of such replica FET transistors (e.g., 203A) for measurement of an input current may be provided for greater matching and defect tolerance.

Replica FET transistor 203A may be coupled to input voltage V_{IN} 102 in parallel to the main FET transistor 203. Replica FET transistor 203A may also be provided the same gate driving clock signal as main FET transistor 203, so that replica FET transistor 203A switches on and off in synchrony with main FET transistor 203. Current sensing circuit 200 may also include a sense amplifier 204 (e.g., using an operational amplifier), whose input terminals may be coupled to the sources (or drains, depending on the configuration employed) of replica FET transistor 203A and main FET transistor 203. The output of sense amplifier 204 may be coupled to the gate terminal of a sense switch 205. When sense switch is turned on due to the output of sense amplifier 204 driving the gate terminal of sense switch 205, the sense switch 205 may turn on and couple the source (or drain, depending on the configuration employed) of replica FET transistor 203A to a sense resistor 206. Thus, a current flowing through replica FET transistor 203A may be sampled via current I_{SENSE} 209 flowing through sense resistor 206. Because replica FET transistor 203A may be sized proportionately to the main FET transistor 203, the current flowing through replica FET transistor 203A (and thus the current I_{SENSE} 209 flowing through sense resistor 206) may be proportional to the input current I_{IN} 104 flowing through main FET transistor 203. The current I_{SENSE} 209 flowing through sense resistor 206 may result in a voltage V_{SENSE} 208 across the sense resistor 206, which may be provided as an input into analog-to-digital converter 207. The output of the analog-to-digital converter 207 may be reported to a controller via a digital interface (e.g., a wired or wireless telemetry interface) as a measurement of the input current I_{IN} 104 flowing through main FET transistor 203.

In some scenarios, measurement of an output current of a switched capacitor power conversion circuit may also be performed using a sense resistor, in a similar manner as described above with respect to measuring the input current of a switched capacitor power conversion circuit. For example, to measure the output current of a dc-dc converter, a sense resistor may be placed in parallel with the output of the dc-dc converter and the voltage measured across the sense resistor (e.g., using sense pins provided in an integrated circuit). The inventors have recognized, however, that measurement of the output current using a sense resistor may result in a loss of power (e.g., I²R resistive loss through heat dissipation), and thus reducing efficiency of the switched capacitor power conversion circuit. Reducing the resistance of the sense resistor may minimize such power loss. In some scenarios, a small resistance, such as the parasitic resistance of an inductance included in the switched capacitor power conversion circuit (e.g., as part of a buck or boost converter circuit), may be utilized as the sense resistor. However, the parasitic resistance of the inductance can vary as much as ±20% across manufactured units. Thus, each production unit may require calibration at the time of manufacture to accurately measure the output current, but this calibration per production unit can be costly to implement. Also, using small resistances may require providing a very small sense voltage to the input of the analog-to-digital converter. Thus, using a small sense resistance could compromise measurement accuracy due to noise in the sense voltage provided to the input of the analog-to-digital converter.

Whether a dedicated sense resistor or parasitic resistance of an inductance is used to measure output current of the switched capacitor power conversion circuit, to limit efficiency loss, the sense voltage V_{SENSE} 208 generated may preferably be very low. To support low sense voltage V_{SENSE} 208, an accurate instrumentation amplifier may be required to amplify the sense voltage V_{SENSE} 208 before providing the amplified voltage to the analog-to-digital converter 207, to utilize the full dynamic range of the analog-to-digital converter 207. This may require dedicating area within the integrated circuit for amplifier components. Voltage amplification may also be power consuming, and accurate amplification may be difficult to achieve in a relatively noisy environment such as a charge pump. Accordingly, the inventors here have recognized, accurately measuring output current I_{OUT} 108 internally within an integrated circuit for a switched capacitor power converter may be relatively a more complex endeavor than measuring the input current I_{IN} 104 into the switched capacitor power conversion circuit.

In disclosed embodiments, the output current of a switched capacitor power conversion circuit may be accurately estimated based on measurement of the input current into the switched capacitor power conversion circuit (which, e.g., may be measured relatively easily using a sense resistor). An ideal charge pump circuit may be modeled as a voltage (or current) multiplier or divider, with a multiplication or division factor of N (e.g., similar to an ideal transformer). Any loss relative to an idealized, conceptual charge pump circuit may be modeled as a voltage (or current) drop or offset at the output of the switched capacitor power conversion circuit. Thus, the output current of a switched capacitor power conversion circuit may be estimated based on measurement of the input current into the switched capacitor power conversion circuit as follows:

I_{OUT}=(I_{IN}×N)−Offset

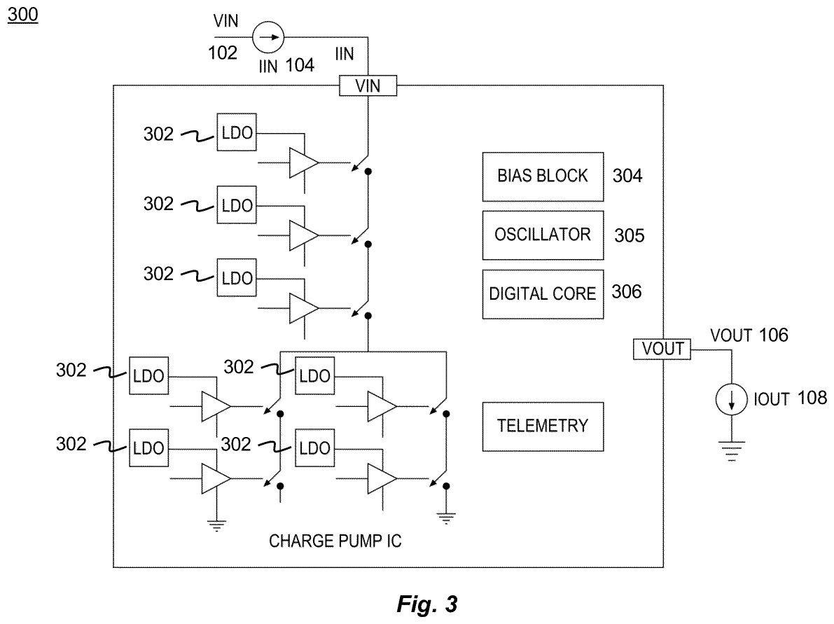

In equation [1], I_{OUT} is the estimated output current of the switched capacitor power conversion circuit, I_{IN} is the measured input current into the switched capacitor power conversion circuit, N is the multiplication or division factor of the switched capacitor power conversion circuit, and the output current offset (Offset) is proportional to the current drawn from the input of the switched capacitor power conversion circuit when no output current is being drawn from the switched capacitor power conversion circuit. With reference to FIG. 3, output current offset may represent input current drawn by the components of the switched capacitor power conversion circuit 300 such as low dropout voltage regulators (LDO 302), bias block 304, oscillator 305, and digital circuitry 306. In preferred embodiments, the output current offset (Offset) is less than or equal to 10 mA. In general, it is expected that lower power switched capacitor power conversion circuits may require a lower output current offset, and higher power switched capacitor power conversion circuits may require a higher output current offset. In preferred embodiments, a ratio of the output current offset to the input current of the switched capacitor power conversion circuit may be about 1% or less.

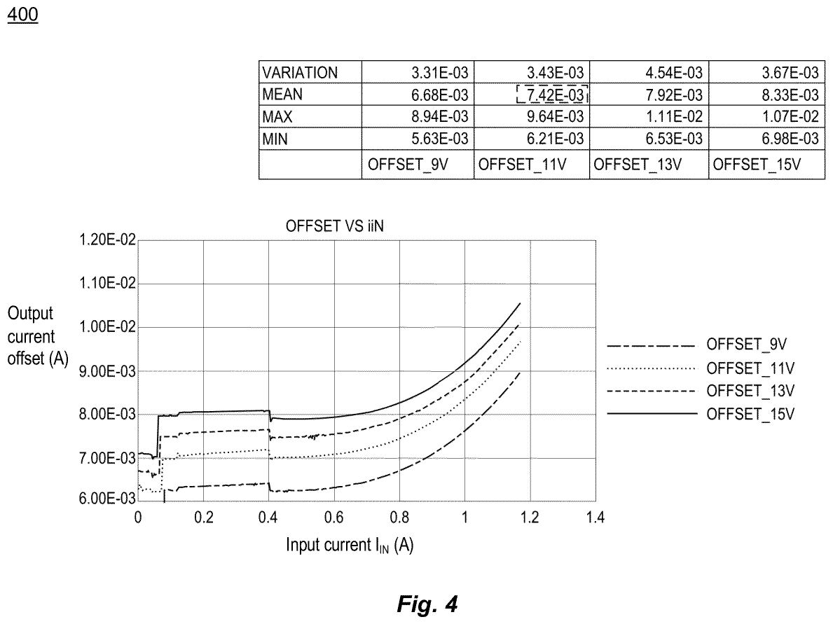

The output current offset may be determined through computer simulation or through one-time evaluation of the switched capacitor power conversion circuit as implemented on silicon or in an integrated circuit form. FIG. 4 illustrates example graphs 400 that may be developed using a one-time evaluation of a switched capacitor power conversion circuit as implemented on silicon or in an integrated circuit form. As shown in FIG. 4, in the one-time evaluation of the switched capacitor power conversion circuit, the input voltage V_{IN} 102 may be set to different values, e.g., 9V, 11V, 13V, or 15V. The input current I_{IN} 104 and/or output current I_{OUT} 108 may be measured using a sense resistor (e.g., using a dedicated sense resistor or parasitic resistance of an inductance in the circuit). In other embodiments, the input current I_{IN} 104 and/or output current I_{OUT} 108 may be measured using a disconnect switch coupled to a replica FET transistor, similar to that described above. The output current offset (y-axis) may be plotted as a function of the input current I_{IN} 104 (x-axis), as shown in FIG. 4, by applying equation [1] above to the measured values of input current I_{IN} 104 and output current I_{OUT} 108.

In some embodiments, a mean value of the output current offset for a given input voltage V_{IN} 102 across the full range of expected input current I_{IN} 104 may be calculated from the collected data. The mean offset may be used for subsequently estimating the value of output current I_{OUT} 108 from the measured input voltage V_{IN} 102 and input current I_{IN} 104.

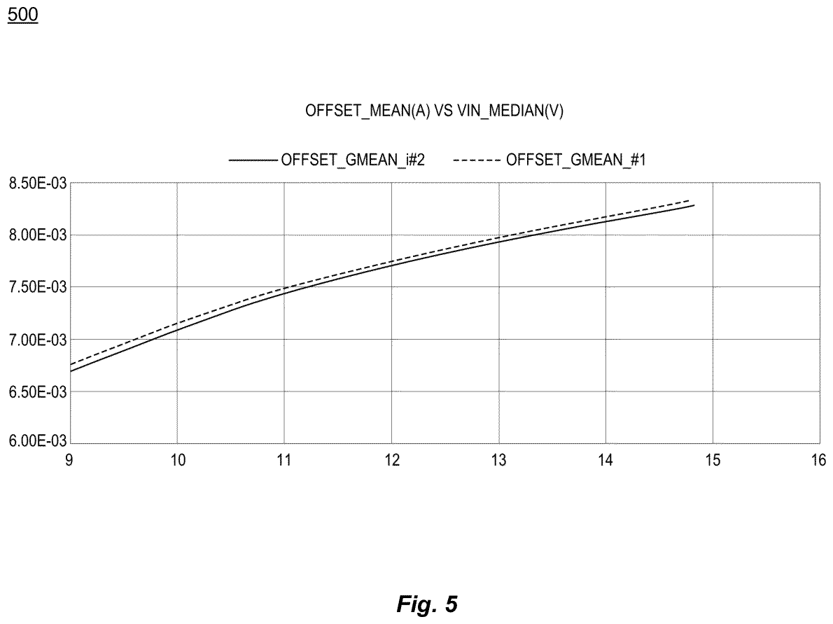

Further, with respect to FIG. 5, in some embodiments, the mean value of the output current offset (y-axis) may be plotted in graph 500 as a function of the input voltage V_{IN} 102 (y-axis). In some embodiments, the mean value of the output current offset across the range of input voltage V_{IN} 102 values may be taken as the output current offset for estimating the value of output current I_{OUT} 108 from the measured input voltage V_{IN} 102 and input current IIrr 104. In alternate embodiments, different output current offset values may be used for different ranges of input voltage V_{IN} 102, as shown in the example table below.

| Input Voltage V_{IN} 102 | Output current offset |
|---|---|
| <10 V | 6.3 mA |
| 10 V-15 V | 7.5 mA |
| 15 V-20 V | 8.5 mA |
| 20 V-25 V | 9.5 mA |

Accordingly, in some embodiments, a wide range of input voltages V_{IN} 102 can be compensated for when estimating output current I_{OUT} 108. Also, in some embodiments, for estimating the value of output current I_{OUT} 108, equation [1] above may be adjusted to account for the output voltage V_{OUT} 106 or the output current I_{OUT} 108 supplying power to the internal components (e.g., low dropout voltage regulators (LDO 302), bias block 304, oscillator 305, and digital circuitry 306) instead of input voltage V_{IN} 102.

In some embodiments, the calculations in accordance with equation [1] for estimating output current I_{OUT} 108 from the measured input voltage V_{IN} 102 and input current I_{IN} 104 may be performed by firmware (e.g., by the controller in the electronic product) or software (e.g., an operating system or application being executed by the electronic product). In alternate embodiments, a hardware circuit (e.g., a field-programmable gate array (FPGA)) may be one-time programmed with the output current offset values to estimate output current I_{OUT} 108 from measured input voltage V_{IN} 102 and input current I_{IN} 104 values. In yet other alternate embodiments, the calculations in accordance with equation [1] for estimating output current I_{OUT} 108 from the measured input voltage V_{IN} 102 and input current I_{IN} 104 may be performed by analog hardware circuitry, in some embodiments included in the same integrated circuit package as the switched capacitor power conversion circuit. In some embodiments, the estimation of output current I_{OUT} 108 from the measured input voltage V_{IN} 102 and input current I_{IN} 104 may be sufficiently accurate to meet customers specifications, one example may be for the USB-C PPS specification.

This disclosure contemplates that the input current may be measured at different locations within the switched capacitor power conversion circuit, including for example measuring input current from a fly capacitor, or measuring the input current from the bias block, oscillator, digital, core, etc. It is to be understood that persons or ordinary skill in the art would be able to appropriately modify the embodiments described above in order to measure input current at these different locations. It should be further understood that depending on the location at which the input current is measured, the output current offset values to estimate output current TO U T 108 from measured input voltage V_{IN} 102 and input current I_{IN} 104 values may vary accordingly, and persons of ordinary skill in the art would understand how to adapt the embodiments above to determine the output current offset values to estimate output current TO U T 108. Further, for example, in some instances a smaller offset of output current may be desired compared to the embodiments described above, and in some other embodiments, a higher offset may be acceptable (e.g., to provide for simplicity of circuit design).

In some embodiments, an electronic product including a switched capacitor power conversion circuit may estimate output current I_{OUT} 108 from measured input voltage V_{IN} 102 and input current I_{IN} 104 values according to the above-described embodiments, and control or regulate the operation of the switched capacitor power conversion circuit according to the estimate output current I_{OUT} 108. For example, the electronic product may modify the measured input voltage V_{IN} 102 to maintain the estimated output current I_{OUT} 108 at a substantially constant value, or regulate the estimated output current I_{OUT} 108 within a range of values, or gradually step up or down the estimated output current I_{OUT} 108 depending on a state of charge of a battery included in the electronic product.

The embodiments may further be described using the following clauses:
1. A method for estimating an output current of a charge pump, comprising:
   measuring, using a first sensing circuit, an input current into a switched capacitor power conversion circuit; and
   calculating, using a hardware processor, an estimated output current from the switched capacitor power conversion circuit as:

I_{OUT}=(I_{IN}×N)−Offset
wherein I_{OUT} is the estimated output current, I_{IN} is the measured input current, N is a multiplication or division factor of the switched capacitor power conversion circuit, and Offset is an output current offset.
2. The method of claim 1, wherein the hardware processor is configured to execute computer-readable instructions to calculate the estimated output current from the switched capacitor power conversion circuit.
3. The method of claim 1, wherein the hardware processor comprises an integrated circuit configured to calculate the estimated output current from the switched capacitor power conversion circuit.
4. The method of claim 1, further comprising:
   measuring, using a second sensing circuit, an input voltage into a switched capacitor power conversion circuit;
   wherein the output current offset is determined based on the measured input voltage.
5. An apparatus for estimating an output current of a charge pump, comprising:
   a first sensing circuit to measure an input current into a switched capacitor power conversion circuit; and
   a hardware processor to calculate an estimated output current from the switched capacitor power conversion circuit as:

I_{OUT}=(I_{IN}×N)−Offset
wherein I_{OUT} is the estimated output current, I_{IN} is the measured input current, N is a multiplication or division factor of the switched capacitor power conversion circuit, and Offset is an output current offset.
6. The apparatus of claim 5, wherein the hardware processor is configured to execute computer-readable instructions to calculate the estimated output current from the switched capacitor power conversion circuit.
7. The apparatus of claim 5, wherein the hardware processor comprises an integrated circuit configured to calculate the estimated output current from the switched capacitor power conversion circuit.
8. The method of claim 5, further comprising:
   a second sensing circuit to measure an input voltage into a switched capacitor power conversion circuit;
   wherein the output current offset is determined based on the measured input voltage.
9. A computer-readable medium storing processor-executable instructions for estimating an output current of a charge pump, the processor-executable instructions comprising instructions to:
   calculate an estimated output current from a switched capacitor power conversion circuit as:

I_{OUT}=(I_{IN}×N)−Offset
wherein I_{OUT} is the estimated output current, I_{IN} is an input current into the switched capacitor power conversion circuit that is measured using a first sensing circuit, N is a multiplication or division factor of the switched capacitor power conversion circuit, and Offset is an output current offset.
10. The medium of claim 9, wherein the output current offset is determined based on an input voltage into the switched capacitor power conversion circuit that is measured using a second sensing circuit.
11. A method for one-time estimation of an output current offset for a charge pump, comprising:
   measuring, using a first sensing circuit, an input current into a switched capacitor power conversion circuit;
   measuring, using a second sensing circuit, an output current from the switched capacitor power conversion circuit;
   calculating, using a hardware processor, a first output current offset for the switched capacitor power conversion circuit using the equation:

I_{OUT}=(I_{IN}×N)−Offset
wherein I_{OUT} is the measured output current, I_{IN} is the measured input current, N is a multiplication or division factor of the switched capacitor power conversion circuit, and Offset is the first output current offset.
12. The method of claim 11, further comprising:
   calculating, using the hardware processor, a second output current offset for the switched capacitor power conversion circuit by averaging the first output current offset across a range of the measured input current.
13. The method of claim 12, further comprising:
   calculating, using the hardware processor, a set of second output current offsets, each calculated second output current offset being calculated for a different input voltage; and
   calculating, using the hardware processor, a third output current offset as an average of the set of second output current offsets.
14. The method of claim 12, further comprising:
   calculating, using the hardware processor, a set of second output current offsets, each calculated second output current offset being calculated for a different input voltage; and
   calculating, using the hardware processor, a set of third output current offsets, each third output current offset corresponding to a different range of input voltage.

The terms used in this specification generally have their ordinary meanings in the art and in the specific context where each term is used. The use of examples in this specification, including examples of any terms discussed herein, is illustrative only, and in no way limits the scope and meaning of the disclosure or of any exemplified term. Likewise, the present disclosure is not limited to various embodiments given in this specification.

Although the terms “first,” “second,” etc., may be used herein to describe various elements, these elements should not be limited by these terms. These terms are used to distinguish one element from another. For example, a first element could be termed a second element, and, similarly, a second element could be termed a first element, without departing from the scope of the embodiments. As used herein, the term “and/or” includes any and all combinations of one or more of the associated listed items.

Spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

In this disclosure, the term “coupled” may also be termed as “electrically coupled”, and the term “connected” may be termed as “electrically connected”. “Coupled” and “connected” may also be used to indicate that two or more elements cooperate or interact with each other.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method for estimating an output current of a charge pump, comprising:
measuring, using a first sensing circuit, an input current into a switched capacitor power conversion circuit; and
calculating, using a hardware processor, an estimated output current from the switched capacitor power conversion circuit as:
I_{OUT}=(I_{IN}×N)−Offset
wherein I_{OUT} is the estimated output current, I_{IN} is the measured input current, N is a multiplication or division factor of the switched capacitor power conversion circuit, and Offset is an output current offset.

2. The method of claim 1, wherein the hardware processor is configured to execute computer-readable instructions to calculate the estimated output current from the switched capacitor power conversion circuit.

3. The method of claim 1, wherein the hardware processor comprises an integrated circuit configured to calculate the estimated output current from the switched capacitor power conversion circuit.

4. The method of claim 1, further comprising:
measuring, using a second sensing circuit, an input voltage into a switched capacitor power conversion circuit;
wherein the output current offset is determined based on the measured input voltage.

5. An apparatus for estimating an output current of a charge pump, comprising:
a first sensing circuit to measure an input current into a switched capacitor power conversion circuit; and
a hardware processor to calculate an estimated output current from the switched capacitor power conversion circuit as:
I_{OUT}=(I_{IN}×N)−Offset
wherein I_{OUT} is the estimated output current, I_{IN} is the measured input current, N is a multiplication or division factor of the switched capacitor power conversion circuit, and Offset is an output current offset.

6. The apparatus of claim 5, wherein the hardware processor is configured to execute computer-readable instructions to calculate the estimated output current from the switched capacitor power conversion circuit.

7. The apparatus of claim 5, wherein the hardware processor comprises an integrated circuit configured to calculate the estimated output current from the switched capacitor power conversion circuit.

8. The apparatus of claim 5, further comprising:
a second sensing circuit to measure an input voltage into a switched capacitor power conversion circuit;
wherein the output current offset is determined based on the measured input voltage.

9. A computer-readable medium storing processor-executable instructions for estimating an output current of a charge pump, the processor-executable instructions comprising instructions to:
calculate an estimated output current from a switched capacitor power conversion circuit as:
I_{OUT}=(I_{IN}×N)−Offset
wherein I_{OUT} is the estimated output current, I_{IN} is an input current into the switched capacitor power conversion circuit that is measured using a first sensing circuit, N is a multiplication or division factor of the switched capacitor power conversion circuit, and Offset is an output current offset.

10. The medium of claim 9, wherein the output current offset is determined based on an input voltage into the switched capacitor power conversion circuit that is measured using a second sensing circuit.

11. A method for one-time estimation of an output current offset for a charge pump, comprising:
measuring, using a first sensing circuit, an input current into a switched capacitor power conversion circuit;
measuring, using a second sensing circuit, an output current from the switched capacitor power conversion circuit;
calculating, using a hardware processor, a first output current offset for the switched capacitor power conversion circuit using the equation:
I_{OUT}=(I_{IN}×N)−Offset
wherein I_{OUT} is the measured output current, I_{IN} is the measured input current, N is a multiplication or division factor of the switched capacitor power conversion circuit, and Offset is the first output current offset.

12. The method of claim 11, further comprising:
calculating, using the hardware processor, a second output current offset for the switched capacitor power conversion circuit by averaging the first output current offset across a range of the measured input current.

13. The method of claim 12, further comprising:
calculating, using the hardware processor, a set of second output current offsets, each calculated second output current offset being calculated for a different input voltage; and
calculating, using the hardware processor, a third output current offset as an average of the set of second output current offsets.

14. The method of claim 12, further comprising:
calculating, using the hardware processor, a set of second output current offsets, each calculated second output current offset being calculated for a different input voltage; and
calculating, using the hardware processor, a set of third output current offsets, each third output current offset corresponding to a different range of input voltage.
